(19) United States
(12) Patent Application Publication
(10) Pub. No.: US 2026/0219504 A1
(43) Pub. Date: Jul. 30, 2026

(54) ELECTRONIC DEVICE AND METHOD FOR OPERATING THE SAME

(71) Applicant: SEMICONDUCTOR ENERGY LABORATORY CO., LTD., Atsugi-shi, Kanagawa-ken (JP)

(72) Inventors: Ryo HATSUMI, Hadano, Kanagawa (JP); Hisao IKEDA, Zama, Kanagawa (JP); Daiki NAKAMURA, Atsugi, Kanagawa (JP); Tomotaka NISHIMURA, Kawasaki, Kanagawa (JP)

(21) Appl. No.: 19/146,985

(22) PCT Filed: Feb. 2, 2024
(86) PCT No.: PCT/IB2024/050958

§ 371 Date: Jul. 10, 2025

(30) Foreign Application Priority Data
Feb. 9, 2023 (JP) 2023-018043

(51) Int. Cl. G02B 27/01; G06F 3/01; G09G 3/3208

(52) U.S. Cl. CPC G02B 27/0172; G06F 3/012; G06F 3/013; G09G 3/3208; G02B 2027/0178

(57) ABSTRACT

An electronic device where the amount of data transfer is reduced is provided. The electronic device is a head-mounted type electronic device that includes a display panel, an optical device, and a direction detection sensor. A display portion of the display panel includes a first region including a pixel array center, a second region adjacent to the outside of the first region, and a third region adjacent to the outside of the second region. The definition of the first region is higher than the definition of the second region, and the definition of the second region is higher than the definition of the third region. Head tracking using the direction detection sensor makes video of the display portion follow a user's head movement so that a user's line of sight can be maintained in the first region that has the highest definition.

### TECHNICAL FIELD

One embodiment of the present invention relates to an electronic device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an imaging device, an operation method thereof, and a manufacturing method thereof.

Note that in this specification and the like, a semiconductor device generally means a device that can function by utilizing semiconductor characteristics. A transistor and a semiconductor circuit are embodiments of semiconductor devices. In addition, in some cases, a memory device, a display device, an imaging device, or an electronic device includes a semiconductor device.

### BACKGROUND ART

Goggles-type devices and glasses-type devices have been developed as electronic devices for XR (XR is a general term for virtual reality (VR), augmented reality (AR), mixed reality (MR), and the like).

In addition, examples of display panels that are used for these electronic devices typically include a display device including a liquid crystal element and a display device including an organic EL (Electro Luminescence) element, a light-emitting diode (an LED), or the like.

A display device including an organic EL element does not need a backlight that is necessary for a liquid crystal display device; thus, a thin, lightweight, high-contrast, and low-power-consumption display device can be achieved. Patent Document 1, for example, discloses an example of a display device using an organic EL element.

### REFERENCE

### Patent Document

[Patent Document 1] Japanese Published Patent Application No. 2018-107444

### SUMMARY OF THE INVENTION

### Problems to be Solved by the Invention

In an XR device such as a goggles-type device, a screen-door effect where a mesh pattern caused by boundaries between pixels in a display panel becomes visible sometimes hinders user's sense of immersion and realistic feeling. The screen-door effect can be mitigated by using a high-definition display panel with high pixel density; however, displaying smooth video also requires a high frame rate. In general, it can be said that the higher the number of pixels (resolution) and the frame rate of the display panel become, the higher video quality becomes.

The display panel performs display using image data transferred from a peripheral device. The peripheral device is required to have capability of generating image data by high-speed rendering. The display panel is also required to have capability of writing the image data at high speed to perform display. In the case where an image is displayed with high definition and at a high frame rate, the amount of image data becomes enormous, resulting in many technical challenges for both the peripheral device and the display panel.

Therefore, electronic devices that have introduced a technology called foveated rendering, which tracks a user's line of sight, performs high-definition display for central vision, and performs low-definition display for peripheral vision in image display, are being commercialized.

A fovea centralis on the retina of a human eye and its neighborhood contribute to vision with high resolving power. However, resolving power in a region that is far from the fovea centralis on the retina is not as high as that of the fovea centralis. Therefore, even when high-definition display is performed on a display region corresponding to the peripheral vision, humans cannot recognize its effect. Accordingly, a rendering load can be reduced by lowering the definition of the display region corresponding to the peripheral vision.

Meanwhile, the foveated rendering technology is insufficient in addressing technical challenges related to the frame rate of the display panel and the amount of data transfer; thus, practical measures to mitigate these technical challenges are desired.

Thus, one object of one embodiment of the present invention is to provide an electronic device where the amount of data transfer is reduced. Another object is to provide an electronic device with a lower frame rate. Another object is to provide an electronic device with a reduced rendering load. Another object is to provide a low-power-consumption electronic device. Another object is to provide an electronic device that can be manufactured at low cost. Another object is to provide a novel electronic device. Another object is to provide a method for operating the electronic device.

Note that the description of these objects does not preclude the presence of other objects. Note that in one embodiment of the present invention, there is no need to achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to an electronic device where the amount of data transfer, a frame rate, and a rendering load are reduced, and a method for operating the electronic device.

One embodiment of the present invention is a head-mounted type electronic device that includes a display panel, an optical device, and a first sensor. The optical device has a function of converging light emitted from a display portion of the display panel to emit the converged light to a user's eye. The first sensor has a function of supporting head tracking. The display portion includes a first region including a pixel array center, a second region adjacent to an outside of the first region, and a third region adjacent to an outside of the second region. Definition of the first region is higher than definition of the second region, and the definition of the second region is higher than definition of the third region. The head tracking makes video of the display portion follow a user's head movement so that a user's line of sight is maintained in the first region.

The electronic device may further include a second sensor. The second sensor may have a function of supporting eye tracking. The eye tracking may move the video of the display portion in a direction opposite to an inclined direction of the user's line of sight so that the user's line of sight is maintained in the first region.

The first region, the second region, and the third region can have the same pixel density. Alternatively, pixel density of the first region may be higher than pixel density of the second region, and the pixel density of the second region may be higher than pixel density of the third region.

When the display portion is visually recognized through the optical device, it is preferable that display of the first region be visually recognized in a region where a viewing angle ranges from 0° to 50° and that display of the third region be visually recognized in a region where the viewing angle is higher than or equal to 70°.

A pixel included in the third region does not necessarily include a subpixel. In addition, the pixel included in the third region preferably emits green light or white light.

It is preferable that the display portion be divided into a plurality of regions, each of the regions include a pixel and a driver circuit for driving the pixel, and that the pixel be placed to include a region overlapping the driver circuit.

It is preferable that the pixel include a transistor including a metal oxide in a channel formation region and that the driver circuit include a transistor including silicon in a channel formation region.

The display panel preferably includes an organic EL element.

Another embodiment of the present invention is a method for operating an electronic device that includes a display panel, an optical device, and a first sensor. Head tracking is performed using the first sensor. The head tracking makes video of the display panel follow a user's head movement so that a user's line of sight through the optical device enters a first region where a viewing angle ranges from 0° to 50°.

Another embodiment of the present invention is a method for operating an electronic device that includes a display panel, an optical device, a first sensor, and a second sensor. Head tracking is performed using the first sensor. The head tracking makes video of the display panel follow a user's head movement so that a user's line of sight through the optical device enters a first region where a viewing angle ranges from 0° to 50°. Eye tracking is performed using the second sensor. The eye tracking moves the video of the display panel in a direction opposite to an inclined direction of the user's line of sight so that the user's line of sight is maintained in the first region.

In the display panel, display with first definition can be performed on the first region; display with second definition can be performed on a second region provided outside the first region; the first definition can be made higher than the second definition; and the definition in the second region can be made lower than the definition in the first region by input of the same image data to a plurality of pixels.

In the display panel, display can be performed at a first frame rate on the first region; display can be performed at a second frame rate on a second region provided outside the first region; and the first frame rate can be made higher than the second frame rate.

### Effect of the Invention

According to one embodiment of the present invention, an electronic device where the amount of data transfer is reduced can be provided. Alternatively, an electronic device with a lower frame rate can be provided. Alternatively, an electronic device with a reduced rendering load can be provided. Alternatively, a low-power-consumption electronic device can be provided. Alternatively, an electronic device that can be manufactured at low cost can be provided. Alternatively, a novel electronic device can be provided. Alternatively, a method for operating the electronic device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1A is a diagram illustrating an electronic device. FIG. 1B is a diagram illustrating a display portion of a display panel.

FIG. 2 is a diagram illustrating a display unit.

FIG. 3A and FIG. 3B are diagrams illustrating regions of the display panel and viewing angles.

FIG. 4A and FIG. 4B are diagrams illustrating display components and lines of sight.

FIG. 5 is a diagram illustrating a structure example of a display portion of the display panel.

FIG. 6 is a diagram illustrating a structure example of a display portion of the display panel.

FIG. 7 is a diagram illustrating a structure example of a display portion of the display panel.

FIG. 8A to FIG. 8E are diagrams illustrating structure examples of the display panel.

FIG. 9A to FIG. 9C are diagrams illustrating the regions of the display panel.

FIG. 10A to FIG. 10C are diagrams illustrating structure examples of a display panel.

FIG. 11A and FIG. 11B are diagrams each illustrating a structure example of a display panel.

FIG. 12A to FIG. 12F are diagrams illustrating structure examples of pixels.

FIG. 13A and FIG. 13B are diagrams illustrating structure examples of a display panel.

FIG. 14 is a diagram illustrating a structure example of a display panel.

FIG. 15 is a diagram illustrating a structure example of a display panel.

FIG. 16 is a diagram illustrating a structure example of a display panel.

FIG. 17 is a diagram illustrating a structure example of a display panel.

FIG. 18 is a diagram illustrating a structure example of a display panel.

FIG. 19 is a diagram illustrating a structure example of a display panel.

FIG. 20A and FIG. 20B are diagrams illustrating a transistor.

FIG. 21A and FIG. 21B are diagrams illustrating a transistor.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are divided and arranged in a plurality of positions.

In addition, one conductor has a plurality of functions such as a wiring, an electrode, and a terminal in some cases. In this specification, a plurality of names are used for the same component in some cases. Furthermore, even in the case where elements are illustrated in a circuit diagram as if they were directly connected to each other, the elements may actually be connected to each other through one or more conductors. In this specification, even such a structure is included in the category of direct connection.

### Embodiment 1

In this embodiment, an electronic device according to one embodiment of the present invention and a method for operating the electronic device will be described.

One embodiment of the present invention is a head-mounted type electronic device such as a goggles-type device or a glasses-type device, which includes a display panel, an optical device, and a direction detection sensor. The optical device has a function of converging light emitted from a display portion of the display panel to emit the converged light to a user's eye. In addition, the direction detection sensor is a sensor for supporting head tracking and can detect a head movement. Furthermore, a sensor for supporting eye tracking may be included as the direction detection sensor.

The display portion includes a first region including a pixel array center, a second region adjacent to the outside of the first region, and a third region adjacent to the outside of the second region. In addition, the first region, the second region, and the third region are listed in order of the definition of the display portion (the definition of the first region>the definition of the second region>the definition of the third region).

With the above structure, the head tracking using the direction detection sensor makes video of the display portion follow a user's head movement so that a user's line of sight can be maintained in the first region. In addition, eye tracking may be concurrently used.

In central vision centering on the user's line of sight, visual information is obtained from a high-definition image that is always displayed on the first region. In peripheral vision, visual information is obtained from a low-definition image that is displayed on the second region and the third region. In a human eye, the resolving power of peripheral vision is low, which can eliminate the need for high-definition display on a region corresponding to the peripheral vision. In addition, display at a low frame rate, monochrome display, or the like as well as making low definition (low pixel density) may be performed on the second region and the third region.

With such a structure and operation, a rendering load can be reduced and the amount of data transfer can be reduced, so that power consumption of the whole electronic device can be reduced.

Note that in this specification, pixel density refers to the number of pixels per unit area or unit length. A display panel with higher pixel density can display a higher-definition image. The pixel density can be expressed by, for example, ppi (pixels per inch), which is the number of pixels per inch (unit length). Note that in some cases, a plurality of pixels A are treated as one pixel B and lower-definition display is performed. In that case, pixel density for each of the pixel A and the pixel B can be defined.

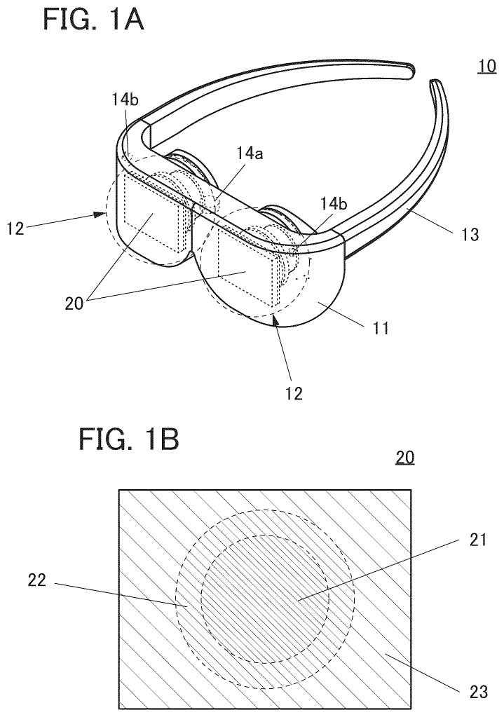

FIG. 1A is a diagram illustrating an electronic device that is one embodiment of the present invention. An electronic device 10 includes two display units 12 and a direction detection sensor 14 (direction detection sensors 14a and 14b) in a housing 11, and includes a band 13 that is connected to the housing 11. The electronic device 10 can be mounted on ahead by the band 13. Note that the band 13 is just an example, and the electronic device 10 may be mounted on a head by another mounting tool such as that of an ear-hanging type or a hat-type. The direction detection sensor 14 can be used to support a head tracking function and an eye tracking function that are described later.

One of the display units 12 incorporated in the housing 11 is for a right eye, and the other of the display units 12 is for a left eye. Each of the display units 12 displays an image corresponding to parallax, so that the user can perceive the image as a three-dimensional image.

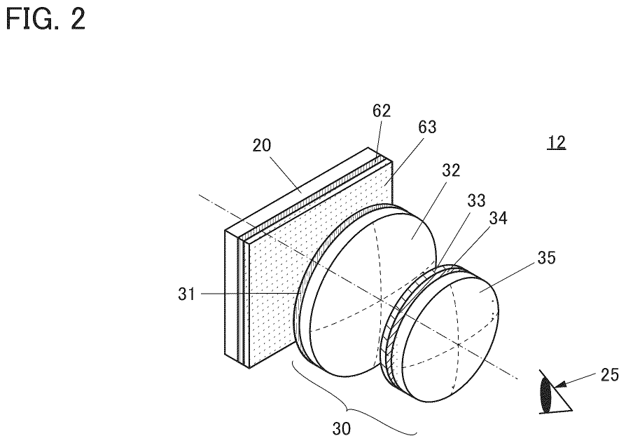

FIG. 2 is a diagram illustrating the display unit 12 illustrated in FIG. 1A. The display unit 12 includes a display panel 20 and an optical device 30, and a display portion (a display surface) of the display panel 20 is placed to perpendicularly cross an optical axis of the optical device 30. A linear polarizing plate 62 and a retardation plate 63 can be attached to the display surface of the display panel 20.

The optical device 30 can include a half mirror 31, a lens 32, a retardation plate 33, a reflective polarizing plate 34, and a lens 35, for example. The optical device 30 is also referred to as a pancake lens in some cases because of its thin shape.

The optical device 30 with such a structure is used to convert light emitted from the display panel 20 into linearly polarized light or circularly polarized light and utilize the converted linearly polarized light or circularly polarized light, so that reflection and transmission can be selectively performed with a component placed on optical path length. Therefore, the optical path length can be secured in limited space, and the display unit 12 can be downsized. Note that the structure of the optical device 30 is not limited, and an enlarging optical system for enlarging and visually recognizing an image of the display panel 20 can be used.

FIG. 1B is a diagram illustrating the display portion of the display panel 20 included in the display unit 12. The display portion of the display panel 20 includes a pixel array where pixels are arranged, and includes a region 21 including a pixel array center, a region 22 adjacent to the outside of the region 21, and a region 23 adjacent to the outside of the region 22.

Here, characteristics of a human eye are described. A human retina has two types of photoreceptor cells: a pyramidal cell and a rod cell. The pyramidal cell has low light sensitivity and is responsible for obtaining visual information in a bright place. In other words, the pyramidal cell largely contributes to eyesight in a bright place. In addition, the pyramidal cell has high sensitivity to light with three wavelengths (red, green, and blue) and thus can identify colors. On the other hand, the rod cell has high light sensitivity, is responsible for obtaining visual information in a dark place, but cannot identify colors.

Pyramidal cells are mainly present in the center of the retina, and rod cells are mainly present in the periphery of the retina. The higher the density of the pyramidal cells in the center of the retina becomes, the higher resolving power (eyesight) becomes; thus, a small difference in shape can be identified in central vision. In contrast, in the periphery where the pyramidal cells have low density, resolving power (eyesight) is low and it is impossible to identify colors; thus, brightness, not shapes and colors, is mainly identified in peripheral vision.

One embodiment of the present invention is a structure where the characteristics of the human eye are incorporated in a display panel. As described above, the center of the display panel 20 requires high resolution, while the periphery does not require high resolution. Furthermore, in the periphery, it is also possible to reduce elements used to represent full colors. By making the center of the display panel 20 have high definition and the periphery have low definition, or by performing such operation, it is possible to incorporate the characteristics of the human eye into the display panel.

Thus, in the display panel 20, the region 21 corresponding to the central vision can have high definition (high pixel density), while the region 22 and the region 23 corresponding to the peripheral vision can have low definition (low pixel density). Since there is no clear boundary between the central vision and the peripheral vision, when there is a boundary with a drastic change in definition, people recognize such a change, which hinders immersion and the like. Therefore, it is preferable to include at least three or more regions with different definitions in the display portion and gradually decrease the definitions from the center to the outside. In this embodiment, the definition of the region 22 is made lower than that of the region 21 and made higher than that of the region 23. Note that the region 22 may include two or more regions with different definitions.

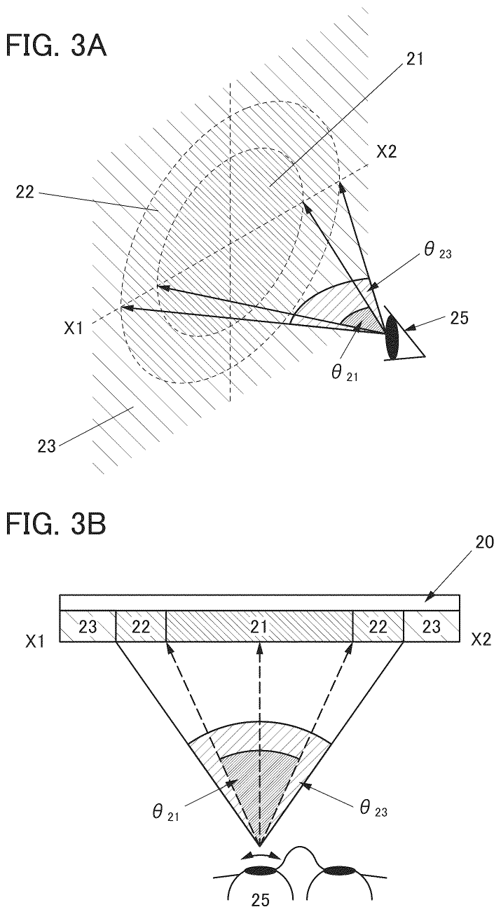

FIG. 3A and FIG. 3B are diagrams illustrating viewing angles at which the region 21, the region 22, and the region 23 are visually recognized. Note that although actually a person (an eye 25) visually recognizes an image of the display panel 20 through the optical device 30 as illustrated in FIG. 2, the optical device 30 is not illustrated here for clarity. In addition, numerical values of viewing angles to be described below are values when the person (the eye 25) visually recognizes the image of the display panel 20 through the optical device 30.

FIG. 3A is a perspective view illustrating viewing angles corresponding to the region 21, the region 22, and the region 23, and FIG. 3B is a diagram corresponding to a cross section along X1-X2 illustrated in FIG. 3A.

In the display portion of the display panel 20, the region 21 is provided in a position where the viewing angle is in a range of θ₂₁, and the region 22 is provided in a position where the viewing angle is in a range of θ₂₃ and does not overlap the region 21.

When considering a movement of a line of sight, in general, tilting the line of sight by ±35° or more from the state of visually recognizing the front does not occur unless there is an intentional movement of eyeballs. Usually, when a person follows an object with his or her eyes, he or she concurrently moves his or her head and line of sight. Therefore, it is said that the angle of rotation of the eyeballs is at most approximately ±25°. In other words, it can be said that a region where display can be visually recognized by the fovea centralis, which has the highest resolving power (eyesight), is in a range of approximately ±25°.

Therefore, the position where the region 21 is provided is in a range where the viewing angle θ₂₁ is from 0° to 50° (±25°).

Furthermore, as it is apart from the fovea centralis, the resolving power decreases; however, up to a macula range of approximately ±10° from the fovea centralis, the characteristics of the human eye have slightly high resolving power.

Therefore, the position where the region 22 is provided is in a range where the viewing angle θ₂₂ is from 0° to 70° in consideration of the range of the rotation of the eyeballs and the macula range and does not overlap the region 21 (±10° from the region 21). In addition, the position where the region 23 is provided is out of the range of θ₂₂.

Note that the above description of the region 21, the region 22, and the region 23 is an example in accordance with the characteristics of the human eye, and the region with relatively high definition may be expanded. Although expanding the region with high definition does not affect visual recognition, it reduces the effects of reducing power consumption and the like. Therefore, it is preferable to set the positions where the region 21, the region 22, and the region 23 are provided in the above ranges or in their vicinities as appropriate.

In the case of foveated rendering that takes into consideration the characteristics of the human eye to image data, the definition can be changed in accordance with the line of sight. In contrast, in the case where the display panel is manufactured in consideration of visual characteristics as in one embodiment of the present invention, the definition cannot be changed in accordance with the line of sight.

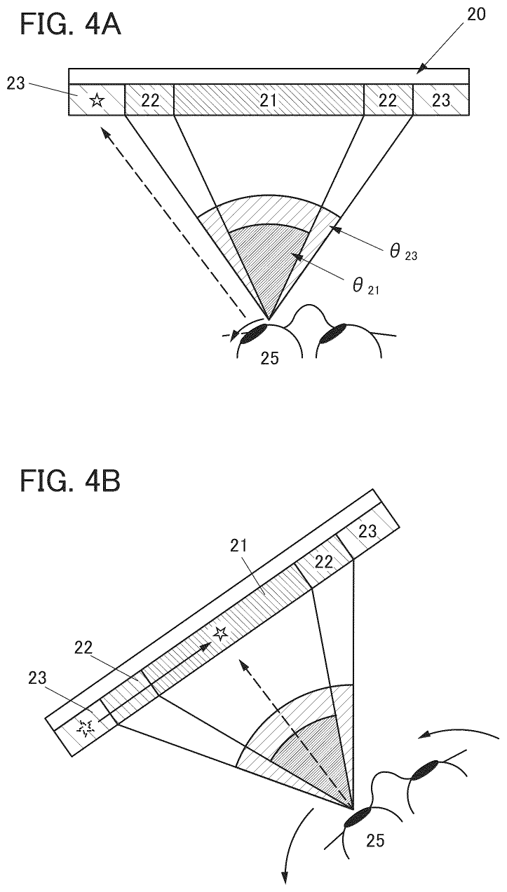

Since a human's line of sight moves, the user does not always see the center of the display portion (the region 21). For example, as illustrated in FIG. 4A, in the case where the line of sight significantly deviates from the center of the display panel 20, the user sees the region 23 in the central vision. As a result, the user strongly feels discomfort due to a decrease in definition of video, a change in color, and the like.

However, as described above, when the person follows an object with his or her eyes, he or she concurrently moves his or her head. Thus, using the head tracking function is effective. As illustrated in FIG. 4B, when the person moves his or her head, the position of the display panel 20 also follows the head movement. Moreover, through the head tracking function, it is possible to display video content that has been in a direction to look at, as indicated by a start mark in FIG. 4A, near the center of the display portion in accordance with the direction of the head, so that the content can be visually recognized in the high-definition region 21.

For head tracking, the direction detection sensor 14a illustrated in FIG. 1A can be used. The direction detection sensor 14a is preferably composed of a combination of one or more of a gyroscope sensor, an acceleration sensor, and a geomagnetic sensor, for example. Through the direction detection sensor 14a, it is possible to detect the head movement and detect a direction where the head (face) is facing. By detecting the head direction, it is possible to make the video follow a user's movement and give the user sense of immersion.

Alternatively, the head tracking function and the eye tracking function may be used in combination. For eye tracking, the direction detection sensor 14b illustrated in FIG. 1A can be used. A near-infrared camera can be used for the direction detection sensor 14b, for example. Images of a reflection point on a cornea and an eyeball are taken using near infrared rays, which have no spectral luminous efficacy, so that the line of sight can be estimated from the fluctuation.

Through the eye tracking function, when the user's line of sight is about to deviate significantly, the video can be moved in a direction opposite to an inclined direction of the line of sight, so that the line of sight can be made to follow the video content to look at, which can prevent the line of sight from deviating from the region 21. Since the user feels discomfort when the video significantly moves only through the eye tracking function, it is preferable to use the eye tracking function in combination with the head tracking function and keep the movement of the video using the eye tracking function small. Note that a structure without the direction detection sensor 14b may be employed.

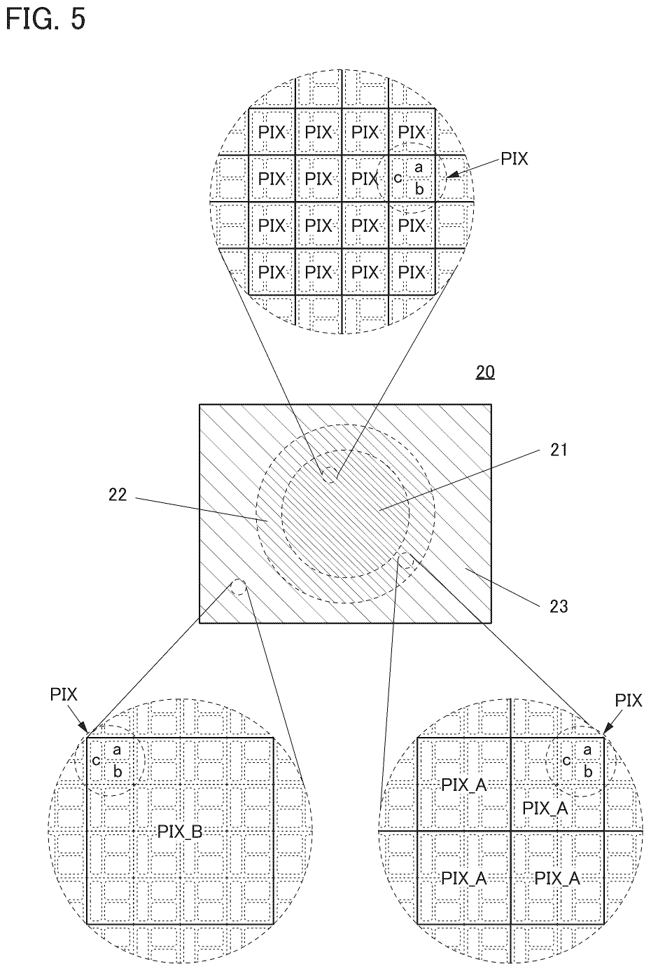

FIG. 5 is a diagram illustrating the display panel 20, and illustrates enlarged views of the region 21, the region 22, and the region 23. The region 21, the region 22, and the region 23 each include pixels PIX. In order to represent full colors, the pixel PIX includes a subpixel a, a subpixel b, and a subpixel c that emit light with different colors. For example, R (red), G (green), and B (blue) can be allocated to the subpixel a, the subpixel b, and the subpixel c, respectively. Note that although FIG. 5 illustrates an example where subpixels employ an S-stripe arrangement, another arrangement such as a stripe arrangement or a PenTile arrangement may be employed.

The display panel 20 illustrated in FIG. 5 includes the pixels PIX with the same size in all the region 21, the region 22, and the region 23. In other words, the region 21, the region 22, and the region 23 have the same pixel density (the pixel density of the region 21=the pixel density of the region 22=the pixel density of the region 23). The region 21 is a region where the highest-definition display is performed and separate image data are input to all the pixels PIX. That is, the region 21 is a region that has high definition and a high rendering load.

The region 22 and the region 23 are regions where display with definition lower than the definition of the region 21 is performed by input of the same image data to a plurality of pixels PIX. For example, in the region 22, the same image signal is input to 2×2 pixels PIX so that the 2×2 pixels PIX operate as one pixel PIX_A. In addition, in the region 23, the same image signal is input to 4×4 pixels PIX so that the 4×4 pixels PIX operate as one pixel PIX_B. Through such operation, the definitions can be gradually decreased from the center to the outside.

Note that in the region 22 and the region 23, the number of pixels PIX to which the same image signal is input is not limited, and for example, the same image signal may be input to 3×3 pixels PIX, 5×5 pixels PIX, 6×6 pixels PIX, or more pixels PIX. Note that in order that the definition of the region 22 be made higher than the definition of the region 23, the number of pixels PIX to which the same image signal is input in the region 22 is made smaller than the number of pixels PIX to which the same image signal is input in the region 23.

In this display method, the region 22 has lower definition than the region 21; thus, the amount of data for constituting an image is small, and a rendering load of the region 22 can be made lower than that of the region 21. In addition, the region 23 has lower definition than the region 22; thus, a rendering load of the region 23 can be made lower than that of the region 22, and power consumption of the electronic device can be reduced.

In addition, in the display panel illustrated in FIG. 5, the region 21, the region 22, and the region 23 can be set depending on a method for inputting image data. Thus, it is not necessary to add a special function to the display panel, and a normal display panel can be used.

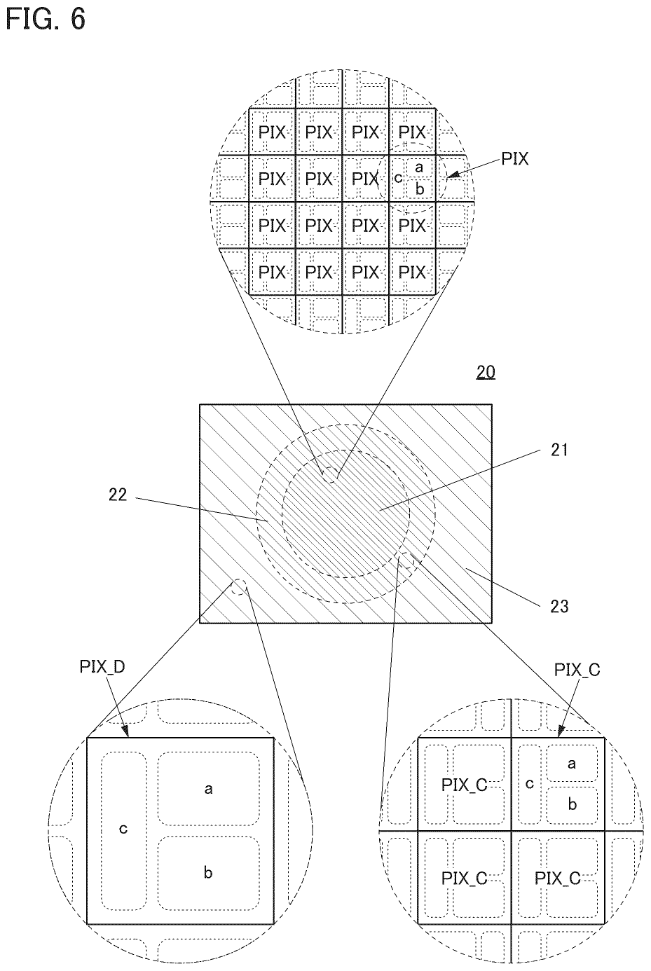

FIG. 6 is a diagram illustrating the display panel 20 that is different from FIG. 5, and illustrates enlarged views of the region 21, the region 22, and the region 23. The region 21 includes the pixels PIX, the region 22 includes the pixels PIX_C, and the region 23 includes the pixels PIX_D. The pixel PIX, the pixel PIX_C, and the pixel PIX_D include the subpixel a, the subpixel b, and the subpixel c that emit light with different colors. For example, R (red), G (green), and B (blue) can be allocated to the subpixel a, the subpixel b, and the subpixel c, respectively.

In a mode of the display panel 20 illustrated in FIG. 6, pixels included in the region 21, the region 22, and the region 23 have different sizes. The region 21 is the highest-definition region, and includes the pixel PIX with the smallest pixel size. That is, the region 21 is a region with high definition, a high rendering load, and a large amount of data transfer.

The region 22 is a region that includes the pixel PIX_C whose size is larger than that of the pixel PIX in the region 21, and the region 23 is a region that includes a pixel PIC_D whose size is larger than that of the pixel PIX_C in the region 22. That is, when the region 21, the region 22, and the region 23 are listed in descending order of pixel density (the pixel density of the region 21>the pixel density of the region 22>the pixel density of the region 23), the definitions are gradually decreased from the center to the outside.

For example, the region 22 can include the pixel PIX_C whose size is 4 times as large as that of the pixel PIX, and the region 23 can include the pixel PIX_D whose size is 16 times as large as that of the pixel PIX. Note that the sizes of the pixel PIX_C and the pixel PIX_D are not limited and can be arbitrarily set within a range that does not cause sense of discomfort in visual recognition. However, in order to make the definition of the region 22 higher than the definition of the region 23, the pixel size of the pixel PIX_C is made smaller than that of the pixel PIX_D (the pixel size of the pixel PIX_C<the pixel size of the pixel PIX_D).

In this structure, the region 22 has lower definition than the region 21; thus, the amount of data for constituting an image is small, and the region 22 can have a lower rendering load than the region 21. In addition, the region 23 has lower definition than the region 22; thus, the region 23 can have a lower rendering load than the region 22. Furthermore, as compared to the structure illustrated in FIG. 5, the number of pixels in the region 22 and the region 23 is small. Thus, the amount of image data transferred from a peripheral device to the display panel can be made small, and power consumption can be further reduced as compared to the structure in FIG. 5.

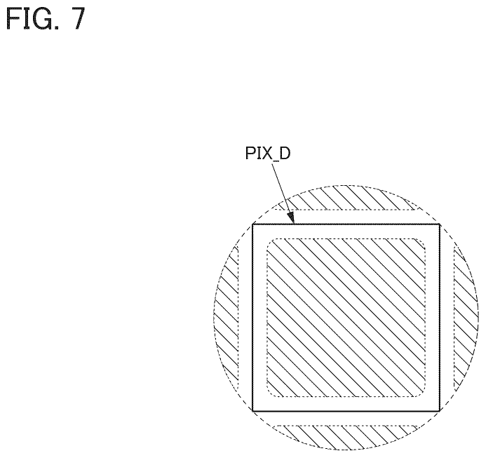

Alternatively, as illustrated in FIG. 7, the pixel PIX_D does not necessarily include subpixels. As described above, owing to the characteristics of the human eye, elements for representing full colors can be reduced in a periphery of the display panel. Therefore, it is not necessary to provide a plurality of subpixels in the pixel PIX_D, and the pixel PIX_D may have a structure for emitting monochromatic light.

Light emitted from the pixel PIX_D is preferably green or white light because brightness is mainly recognized in the peripheral vision. The green or white light has high spectral luminous efficacy and thus can reduce luminance. In the case where a light-emitting device is used for a pixel, power consumption can be reduced. In addition, an aperture ratio can be reduced because no subpixels are provided, which contributes to a reduction in power consumption.

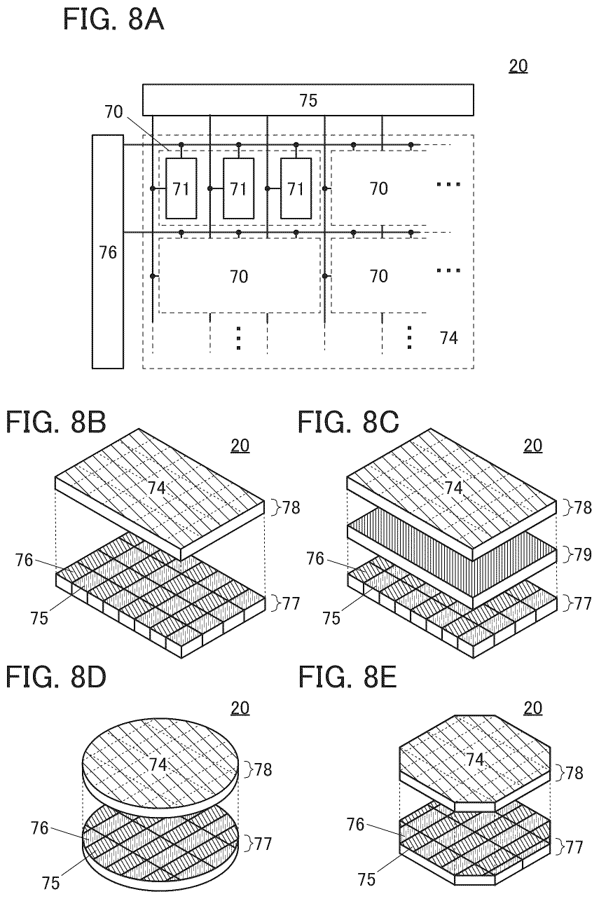

FIG. 8A is a block diagram illustrating the display panel 20 included in the electronic device according to one embodiment of the present invention. The display panel 20 includes a pixel array 74, a circuit 75, and a circuit 76. The pixel array 74 includes pixels 70 arranged in a column direction and a row direction.

The pixel 70 can include a plurality of subpixels 71. The subpixel 71 has a function of emitting light for display. Note that each of the pixels 70 corresponds to the pixel PIX, the pixel PIX_C, or the pixel PIX_D illustrated in FIG. 5 or FIG. 6. Each of the subpixels 71 corresponds to the subpixel a, the subpixel b, or the subpixel c.

Each of the subpixels 71 includes a light-emitting device that emits visible light. An EL element such as an OLED (Organic Light Emitting Diode) or a QLED (Quantum-dot Light Emitting Diode) is preferably used as the light-emitting device. As a light-emitting substance contained in the EL element, a substance that emits fluorescent light (a fluorescent material), a substance that emits phosphorescent light (a phosphorescent material), a substance that exhibits thermally activated delayed fluorescence (a thermally activated delayed fluorescent (TADF) material), an inorganic compound (a quantum dot material or the like), and the like can be given. In addition, an LED (Light Emitting Diode) such as a micro LED can also be used as the light-emitting device. Furthermore, a non-light-emitting device such as a liquid crystal device can be used for each of the subpixels 71.

The circuit 75 and the circuit 76 are driver circuits for driving each of the subpixels 71. The circuit 75 can have a function of a source driver circuit, and the circuit 76 can have a function of a gate driver circuit. A shift register circuit or the like can be used as each of the circuit 75 and the circuit 76, for example.

Note that in the case where pixel drive mode differs depending on the region as illustrated in FIG. 5 or in the case where pixel size differs depending on the region as illustrated in FIG. 6, for example, the display panel may be divided into a plurality of regions vertically and horizontally so that the pixels are driven in each divided region.

For example, as illustrated in FIG. 8B, each of the circuit 75 and the circuit 76 can be divided and placed under the pixel array 74. In that case, the display panel 20 has a stacked-layer structure of a layer 77 and a layer 78, a plurality of circuits 75 and a plurality of circuits 76 are provided in the layer 77, and the pixel array 74 is provided in the layer 78 to overlap the plurality of circuits 75 and the plurality of circuits 76.

In addition, when each of the circuit 75 and the circuit 76 is divided and placed, the pixel array 74 can be driven in each divided region. For example, some of the pixel array 74 can operate at different frame rates. That is, the region 21, the region 22, and the region 23 can operate at different frame rates. Furthermore, in the case where the region 21, the region 22, and the region 23 have different pixel density, for example, driving is facilitated because a system for inputting image data differs depending on the region.

In the peripheral vision, resolving power is low, the region 21 can operate at a first frame rate that is fast, and the region 22 and the region 23 can operate at a second frame rate that is slower than the first frame rate (the first frame rate>the second frame rate). Alternatively, the region 23 may operate at a third frame rate that is slower than the second frame rate of the region 22 (the second frame rate>the third frame rate). By performing such operation, the rendering load can be reduced and the amount of data transfer can be made small. Accordingly, power consumption can be reduced. Operation of varying the frame rate depending on the region is applicable to both the structure in FIG. 5 and the structure in FIG. 6.

In addition, when the driver circuits are provided below the pixel array 74, wiring length can be shortened and wiring capacitance can be reduced. Accordingly, a display panel that can perform high-speed operation and operates with low power consumption can be provided. Furthermore, the display panel 20 can have a narrow bezel.

Note that the layout and area of the circuit 75 and the circuit 76 illustrated in FIG. 8B are examples and can be changed as appropriate. In addition, some of the circuit 75 and the circuit 76 can be formed in the same layer as the pixel array 74. Furthermore, a circuit such as a memory circuit, an arithmetic circuit, or a communication circuit may be provided in the layer 77.

In this structure, for example, the layer 77 can be provided on a single crystal silicon substrate, the circuit 75 and the circuit 76 can be formed with transistors including silicon in channel formation regions (hereinafter Si transistors), and pixel circuits included in the pixel array 74 provided in the layer 78 can be formed with transistors including a metal oxide in channel formation regions (hereinafter OS transistors). An OS transistor can be formed with a thin film and can be formed to be stacked over a Si transistor.

Note that as illustrated in FIG. 8C, a structure where a layer 79 including OS transistors is provided between the layer 77 and the layer 78 may be employed. In the layer 79, OS transistors that form some of the pixel circuits included in the pixel array 74 can be provided. Alternatively, OS transistors that form some of the circuit 75 and the circuit 76 can be provided. Alternatively, OS transistors that form some of the circuits that can be provided in the layer 77, such as a memory circuit, an arithmetic circuit, and a communication circuit, can be provided.

The top surface shape of the display panel 20 is not limited to a rectangle and may be a circle as illustrated in FIG. 8D. Alternatively, a polygon such as an octagon as illustrated in FIG. 8E may be employed.

Note that although FIG. 5, FIG. 6, and the like each illustrate an example where each of the region 21 and the region 22 is concentrically provided in the display portion of the display panel 20, each of the region 21 and the region 22 is not limited to a concentric circle when divisional driving where the display panel 20 is divided into a plurality of regions is employed.

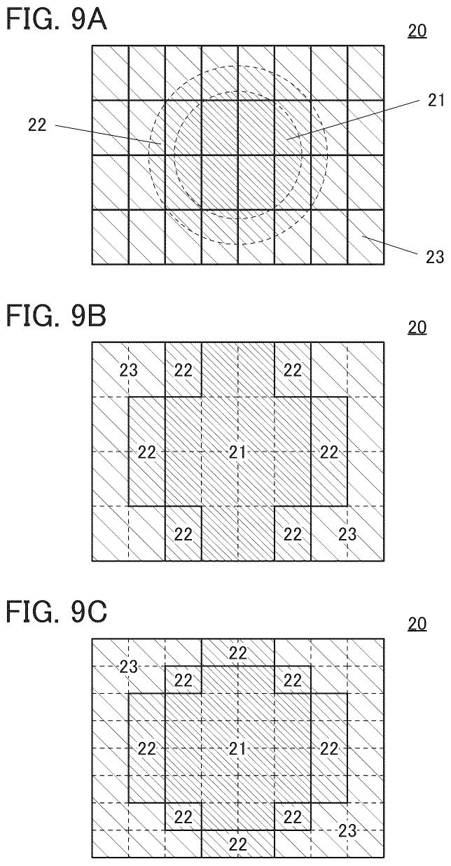

FIG. 9A is a diagram where the display portion of the display panel 20 that has been divided into 32 (4 (vertically)×8 (horizontally)) is superimposed on the region 21, the region 22, and the region 23 that are placed in consideration of the above-described characteristics of the human eye. In this manner, each of the divided regions is a rectangle, and not all the divided regions can match the concentric circular shape of each of the region 21 and the region 22. Therefore, as each of the divided rectangular regions, a high-definition region is preferentially placed.

For example, in FIG. 9A, in the case where one rectangular region includes both the region 21 and the region 22, the rectangular region is treated as the high-definition region 21 regardless of their area ratio. By preferentially placing the high-definition region, it is possible to prevent deviation from visual characteristics, such as recognizing a low-definition region with central vision.

In the case where the number of divisions for the display portion of the display panel 20 is 32, the region 21, the region 22, and the region 23 can be placed as illustrated in FIG. 9B. Alternatively, in the case where the number of divisions for the display portion of the display panel 20 is 64 (8 (vertically)×8 (horizontally)), the region 21, the region 22, and the region 23 can be placed as illustrated in FIG. 9C. Furthermore, by increasing the number of divisions, it is possible to make the positioning of the region 21 and the region 22 closer to a concentric circular shape, which can enhance the effect of reducing power consumption.

At least part of this embodiment can be implemented in combination with the other embodiments described in this specification as appropriate.

### Embodiment 2

In this embodiment, structure examples of a display panel that can be employed for the electronic device according to one embodiment of the present invention will be described. A display panel described below as an example can be employed for the display panel 20 in Embodiment 1.

One embodiment of the present invention is a display panel including light-emitting elements (also referred to as light-emitting devices). The display panel includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers containing different light-emitting materials. For example, when three kinds of light-emitting elements that emit red (R), green (G), and blue (B) light are included, a full-color display panel can be achieved.

In the case of manufacturing a display panel including a plurality of light-emitting elements of different emission colors, at least layers (light-emitting layers) containing light-emitting materials each need to be formed in an island shape. In the case of separately forming some or all of EL layers, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve the high definition and high aperture ratio of the display panel. In addition, the outline of the layer might blur during evaporation, so that the thickness of an end portion might be reduced. That is, the thickness of an island-shaped light-emitting layer might vary from place to place. In addition, in the case of manufacturing a display panel with a large size, high resolution, or high definition, a manufacturing yield might be reduced because of low dimensional accuracy of the metal mask and deformation due to heat or the like. Thus, a measure has been taken for a pseudo increase in definition (also referred to as pixel density) by employing a unique pixel arrangement such as a PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by a photolithography method without using a shadow mask such as a fine metal mask (an FMM). Accordingly, it is possible to achieve a display panel with high definition and a high aperture ratio, which has been difficult to achieve. Moreover, since the EL layers can be formed separately, it is possible to achieve a display panel that performs extremely clear display with high contrast and high display quality. Note that, fine patterning of the EL layers may be performed using both a metal mask and a photolithography method, for example.

In addition, some or all of the EL layers can be physically divided from each other. This can inhibit leakage current flowing between adjacent light-emitting elements through a layer (also referred to as a common layer) shared by the light-emitting elements. Thus, it is possible to prevent light emission due to unintended crosstalk, so that a display panel with extremely high contrast can be achieved. In particular, a display panel having high current efficiency at low luminance can be achieved.

In one embodiment of the present invention, the display panel can also be obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, some or all of the EL layers may be divided from each other in a step using a photolithography method. Thus, leakage current through the common layer is inhibited; accordingly, a high-contrast display panel can be achieved. In particular, when an element has a tandem structure where a plurality of light-emitting layers are stacked with a highly conductive intermediate layer therebetween, leakage current through the intermediate layer can be effectively prevented, so that a display panel with high luminance, high definition, and high contrast can be achieved.

In the case where the EL layer is processed by a photolithography method, part of the light-emitting layer is sometimes exposed to cause degradation. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit degradation of the EL layer and can achieve a highly reliable display panel.

Moreover, between two adjacent light-emitting elements, there is a region (a concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as LFP: Local Filling Planarization) functioning as a planarization film. The resin layer has a function of a planarization film. This structure can inhibit disconnection of the common layer or the common electrode and can achieve a highly reliable display panel.

More specific structure examples of the display panel according to one embodiment of the present invention will be described below with reference to drawings.

### Structure Example 1

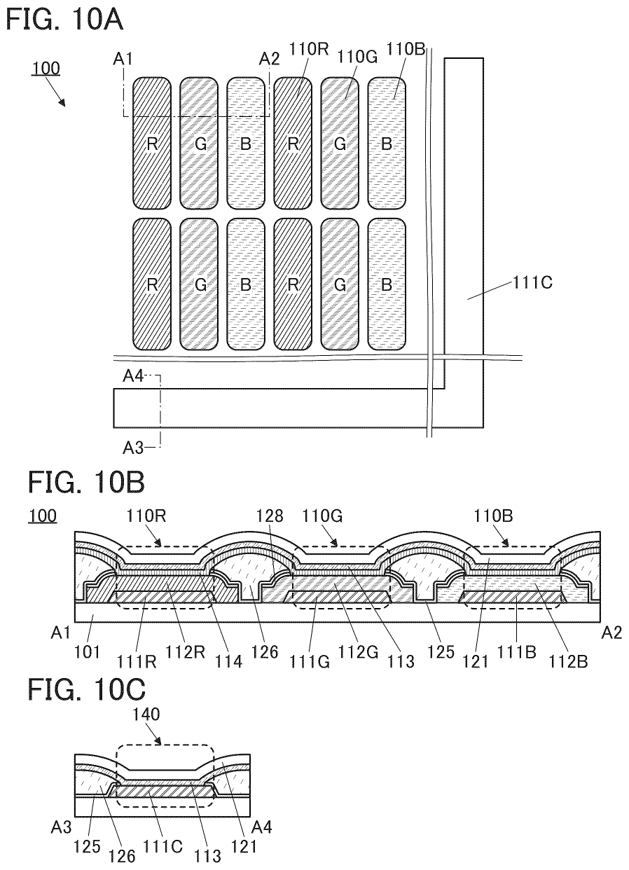

FIG. 10A illustrates a schematic top view of a display panel 100 according to one embodiment of the present invention. The display panel 100 includes, over a substrate 101, a plurality of light-emitting elements 110R exhibiting red, a plurality of light-emitting elements 110G exhibiting green, and a plurality of light-emitting elements 110B exhibiting blue. In FIG. 10A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 10A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As a light-emitting substance contained in the EL element, not only an organic compound but also an inorganic compound (a quantum dot material or the like) can be used.

FIG. 10A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided across two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrilateral shape, or the like. Note that in this specification and the like, atop surface shape refers to a shape in a plan view, i.e., a shape seen from above.

FIG. 10B and FIG. 10C are schematic cross-sectional views corresponding to the dashed-dotted line A1-A2 and the dashed-dotted line A3-A4 in FIG. 10A. FIG. 10B illustrates a schematic cross-sectional view of the light-emitting element 110R, the light-emitting element 110G, and the light-emitting element 110B, and FIG. 10C illustrates a schematic cross-sectional view of a connection portion 140 where the connection electrode 110C and the common electrode 113 are connected to each other.

The light-emitting element 110R includes a pixel electrode 110R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 110B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting substance (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure where the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 110R, the pixel electrode 110G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display panel can be obtained. In contrast, when the pixel electrodes have reflective properties and the common electrode 113 has a light-transmitting property, a top-emission display panel can be obtained. Note that when both the pixel electrodes and the common electrode 113 have light-transmitting properties, a dual-emission display panel can also be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be increased. Furthermore, when the side surface of the pixel electrode 111 has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. In contrast, an organic film formed using an FMM (Fine Metal Mask) or the like has a thickness that tends to gradually decrease with decreasing the distance from an end portion, and has a top surface forming a slope in an area extending in the range of greater than or equal to 1 m and less than or equal to 10 m, for example. Thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to fill end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with a top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 to protect the side surfaces of the organic layer 112.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure where an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. This is preferable because the top surface of the protective layer 121 is made flat and a component (e.g., a color filter, an electrode of a touch sensor, a lens array, or the like) can be provided above the protective layer 121 while being less affected by an uneven shape caused by a lower structure.

FIG. 10C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 10C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display panel whose structure is partly different from that of Structure Example 1 is described below. Note that the above description can be referred to for portions common to those in Structure Example 1, and the description is omitted in some cases.

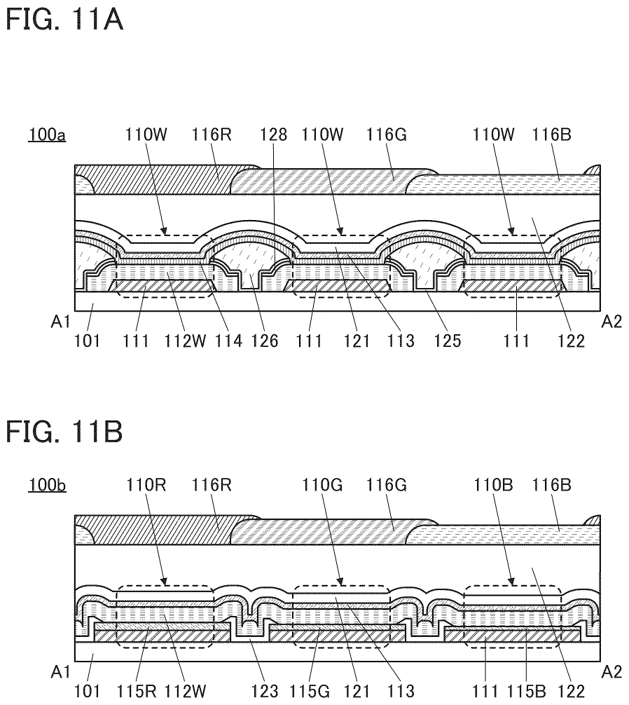

FIG. 11A is a schematic cross-sectional view of a display panel 100a. The display panel 100a is different from the display panel 100 mainly in the structure of the light-emitting element and including a coloring layer.

The display panel 100a includes light-emitting elements 110W that emit white light. The light-emitting elements 110W each include the pixel electrode 111, an organic layer 112W, the common layer 114, and the common electrode 113. The organic layer 112W emits white light. For example, the organic layer 112W can contain two or more kinds of light-emitting materials whose emission colors are complementary colors. For example, the organic layer 112W can contain a light-emitting organic compound that emits red light, a light-emitting organic compound that emits green light, and a light-emitting organic compound that emits blue light. Alternatively, the organic layer 112W may contain a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display panel can achieve high contrast and high color reproducibility.

An insulating layer 122 that functions as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed. Thus, with a flat top surface of the insulating layer 122, the thickness of the coloring layer 116R or the like can be uniform and the color purity of light extracted from each light-emitting element can be increased. Note that when the thickness of the coloring layer 116R or the like is non-uniform, the amount of light absorption varies depending on a place in the coloring layer 116R, which might decrease the color purity.

### Structure Example 3

FIG. 11B is a schematic cross-sectional view of a display panel 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having a property of reflecting and transmitting visible light is used for the common electrode 113, so that a micro resonator (microcavity) structure can be achieved. In that case, by adjusting the thicknesses of the conductive layer 115R, the conductive layer 115G, and the conductive layer 115B to obtain optimal optical path length, light with different wavelengths and increased intensities can be obtained from the light-emitting element 110R, the light-emitting element 110G, and the light-emitting element 110B even when the organic layer 112 that emits white light is used.

Furthermore, the coloring layer 116R, the coloring layer 116G, and the coloring layer 116B are provided on the optical paths of the light-emitting element 110R, the light-emitting element 110G, and the light-emitting element 110B, respectively, so that light with high color purity can be obtained.

In addition, an insulating layer 123 that covers end portions of the pixel electrode 111, the conductive layer 115R, the conductive layer 115G, and the conductive layer 115B is provided. An end portion of the insulating layer 123 preferably has a tapered shape. When the insulating layer 123 is provided, coverage with the organic layer 112W, the common electrode 113, the protective layer 121, and the like provided over the insulating layer 123 can be increased.

The organic layer 112W and the common electrode 113 are each provided as one continuous film shared by the light-emitting elements. Such a structure is preferable because the manufacturing process of the display panel can be greatly simplified.

Here, the end portion of the pixel electrode 111 is preferably substantially perpendicular to the top surface of the substrate 101. Accordingly, a steep portion can be formed on the surface of the insulating layer 123, and thus a thin portion can be formed in part of the organic layer 112W that covers the steep portion or part of the organic layer 112W can be divided. Accordingly, leakage current generated between adjacent light-emitting elements through the organic layer 112W can be inhibited without processing the organic layer 112W by a photolithography method or the like.

The above is the description of the structure example of the display panel.

### [Pixel Layout]

Pixel layout different from that in FIG. 10A will be mainly described below. There is no particular limitation on the arrangement of light-emitting elements (subpixels), and a variety of methods can be employed.

In addition, examples of a top surface shape of the subpixel include polygons such as a triangle, a quadrilateral (including a rectangle and a square), and a pentagon; polygons with rounded corners; an ellipse; and a circle. Here, the top surface shape of the subpixel corresponds to a top surface shape of a light-emitting region of the light-emitting element.

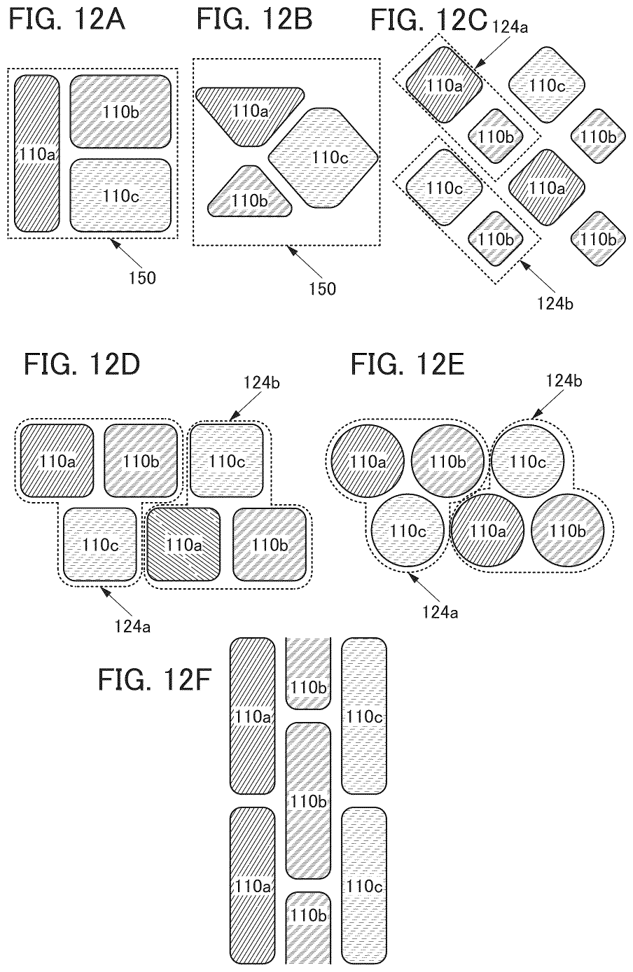

A pixel 150 illustrated in FIG. 12A employs an S-stripe arrangement. The pixel 150 illustrated in FIG. 12A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 12B includes the light-emitting element 110a whose top surface has a rough trapezoidal or rough triangle shape with rounded corners, the light-emitting element 110b whose top surface has a rough trapezoidal or rough triangle shape with rounded corners, and the light-emitting element 110c whose top surface has a rough quadrilateral or rough hexagonal shape with rounded corners. In addition, the light-emitting element 110a has a larger light-emitting area than the light-emitting element 110b. In this manner, the shapes and sizes of the light-emitting elements can be independently determined. For example, the size of a light-emitting element with higher reliability can be made smaller. For example, the light-emitting element 110a may be a green light-emitting element, the light-emitting element 110b may be a red light-emitting element, and the light-emitting element 110c may be a blue light-emitting element.

Pixels 124a and 124b illustrated in FIG. 12C employ a PenTile arrangement. FIG. 12C illustrates an example where the pixels 124a each including the light-emitting element 110a and the light-emitting element 110b and the pixels 124b each including the light-emitting element 110b and the light-emitting element 110c are alternately arranged. For example, the light-emitting element 110a may be a red light-emitting element, the light-emitting element 110b may be a green light-emitting element, and the light-emitting element 110c may be a blue light-emitting element.

The pixels 124a and 124b illustrated in FIG. 12D and FIG. 12E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red light-emitting element, the light-emitting element 110b may be a green light-emitting element, and the light-emitting element 110c may be a blue light-emitting element.

FIG. 12D illustrates an example where the top surface of each light-emitting element has a rough quadrilateral shape with rounded corners, and FIG. 12E illustrates an example where the top surface of each light-emitting element is circular.

FIG. 12F illustrates an example where light-emitting elements of different colors are arranged in a zigzag manner. Specifically, the positions of top sides of two light-emitting elements arranged in a row direction (e.g., the light-emitting element 110a and the light-emitting element 110b or the light-emitting element 110b and the light-emitting element 110c) are not aligned in a top view. For example, the light-emitting element 110a may be a red light-emitting element, the light-emitting element 110b may be a green light-emitting element, and the light-emitting element 110c may be a blue light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the EL layer might have a circular top surface.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in combination with the other embodiments described in this specification as appropriate.

### Embodiment 3

In this embodiment, other structure examples of a display panel that can be employed for the electronic device according to one embodiment of the present invention will be described.

Display panels in this embodiment are high-definition display panels. In particular, the display panels in this embodiment are suitably used for display portions of wearable devices that can be mounted on a head, such as VR devices like head-mounted displays and glasses-type AR devices.

### [Display Module]

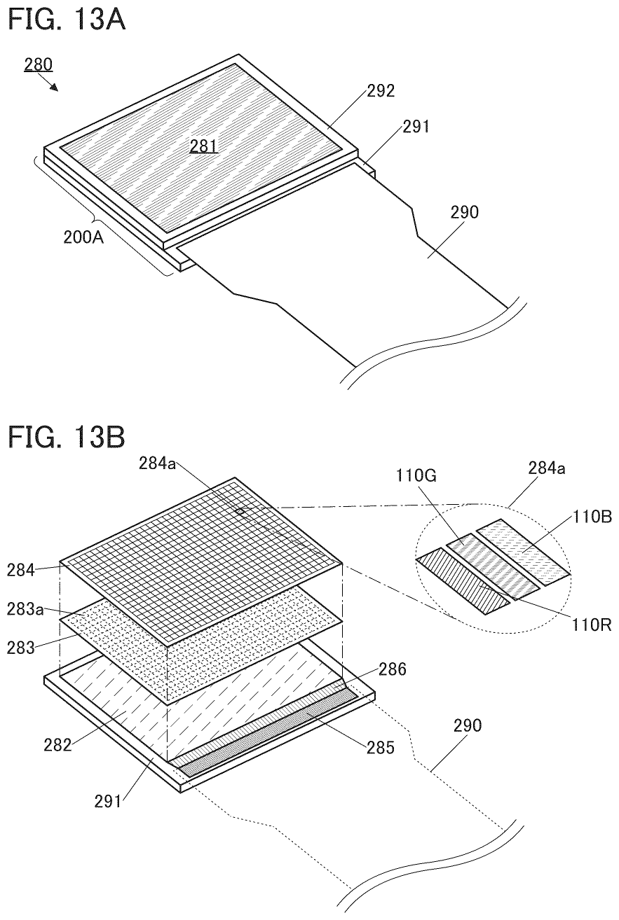

FIG. 13A is a perspective view of a display module 280. The display module 280 includes a display panel 200A and an FPC 290. Note that a display panel included in the display module 280 is not limited to the display panel 200A and may be any of a display panel 200B to a display panel 200F described later.

The display module 280 includes a substrate 291 and a substrate 292. The display module 280 includes a display portion 281. The display portion 281 is a region where an image is displayed.

FIG. 13B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion over the substrate 291 that does not overlap the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 13B. The pixel 284a includes the light-emitting element 110R that emits red light, the light-emitting element 110G that emits green light, and the light-emitting element 110B that emits blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (drive transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of agate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. In addition, an IC may be mounted on the FPC 290.

The display module 280 can have a structure where one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high pixel density. For example, the pixels 284a are preferably arranged in the display portion 281 with a pixel density higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high definition, and thus can be suitably used for a VR device such as a head-mounted display or a glasses-type AR device. For example, even in the case of a structure where the display portion of the display module 280 is seen through a lens, pixels of the extremely-high-definition display portion 281 included in the display module 280 are not seen even when the display portion is enlarged by the lens, so that display providing a high sense of immersion can be performed. Without being limited thereto, the display module 280 can also be suitably used for an electronic device having a comparatively small display portion. For example, the display module 280 can be suitably used for a display portion of a wearable electronic device, such as a wristwatch.

### [Display Panel 200A]

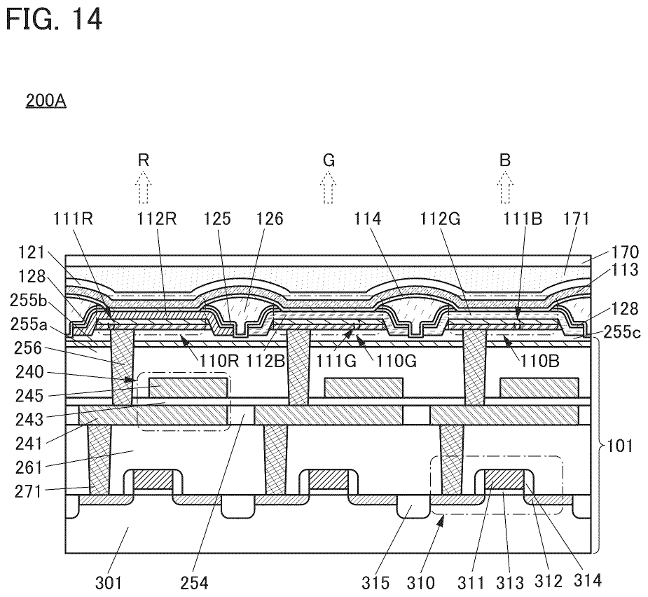

The display panel 200A illustrated in FIG. 14 includes a substrate 301, the light-emitting elements 110R, 110G, and 110B, capacitors 240, and transistors 310.

The substrate 301 corresponds to the substrate 291 in FIG. 13A and FIG. 13B.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layers 314 are provided to cover side surfaces of the conductive layer 311.

In addition, an element isolation layer 315 is provided between two adjacent transistors 310 to be embedded in the substrate 301.

Furthermore, an insulating layer 261 is provided to cover the transistors 310, and the capacitors 240 are provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping the conductive layer 241 with the insulating layer 243 therebetween.

An insulating layer 255a is provided to cover the capacitor 240. An insulating layer 255b is provided over the insulating layer 255a. An insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example where the insulating layer 255c is partly etched and a concave portion is formed, the concave portion is not necessarily provided in the insulating layer 255c.

The light-emitting element 110R that emits red light, the light-emitting element 110G that emits green light, and the light-emitting element 110B that emits blue light are provided over the insulating layer 255c. Embodiment 2 can be referred to for the structures of the light-emitting element 110R, the light-emitting element 110G, and the light-emitting element 110B.

In the display panel 200A, since the light-emitting devices of different colors are separately formed, a change in chromaticity between light emission at low luminance and light emission at high luminance is small. Furthermore, since the organic layers 112R, 112G, and 112B are apart from each other, crosstalk generated between adjacent subpixels can be inhibited while the display panel has high definition. It is thus possible to achieve a display panel that has high definition and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. A top surface of the insulating layer 255c and a top surface of the plug 256 are level with or substantially level with each other. A variety of conductive materials can be used for the plugs.

In addition, the protective layer 121 is provided over the light-emitting elements 110R, 110G, and 110B. A substrate 170 is attached onto the protective layer 121 with an adhesive layer 171.

An insulating layer covering an end portion of a top surface of the pixel electrode 111 is not provided between two adjacent pixel electrodes 111. Thus, the distance between adjacent light-emitting elements can be extremely narrowed. Accordingly, the display panel can have high definition or high resolution.

### [Display Panel 200B]

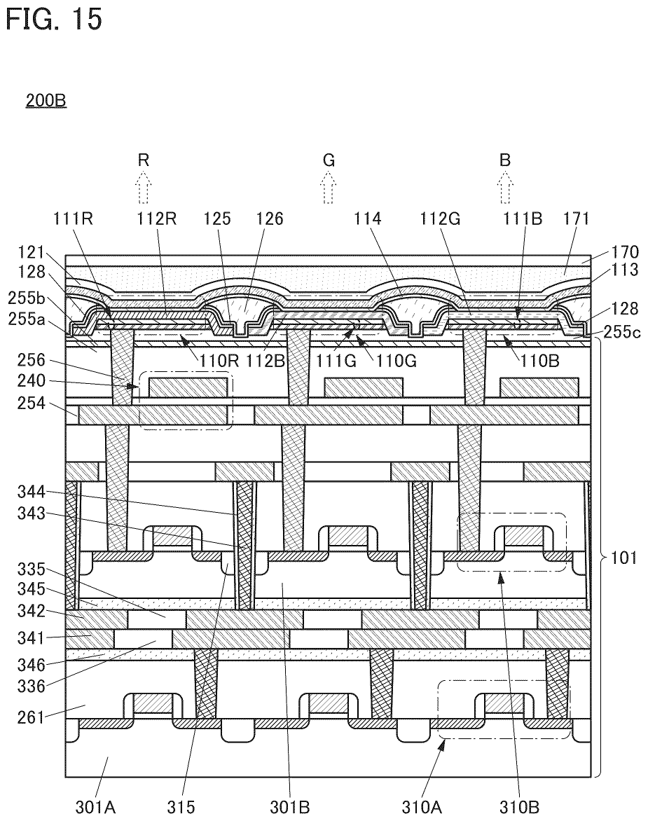

The display panel 200B illustrated in FIG. 15 has a structure where transistors 310A and transistors 310B in each of which a channel is formed in a semiconductor substrate are stacked. Note that in the following description of the display panel, the description of portions similar to those of the above display panel is omitted in some cases.

The display panel 200B has a structure where a substrate 301B provided with the transistors 310B, the capacitors 240, and the light-emitting devices is attached to a substrate 301A provided with the transistors 310A.

Here, an insulating layer 345 is provided on a bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 121 can be used.

The substrate 301B is provided with plugs 343 that penetrate the substrate 301B and the insulating layer 345. Here, insulating layers 344 each functioning as a protective layer are preferably provided to cover side surfaces of the plugs 343.

In addition, a conductive layer 342 is provided on the bottom side of the substrate 301B with the insulating layer 345 therebetween. The conductive layer 342 is embedded in an insulating layer 335, and bottom surfaces of the conductive layer 342 and the insulating layer 335 are planarized. Furthermore, the conductive layer 342 is electrically connected to the plug 343.

In contrast, a conductive layer 341 is provided over the insulating layer 346 over the substrate 301A. The conductive layer 341 is embedded in an insulating layer 336, and top surfaces of the conductive layer 341 and the insulating layer 336 are planarized.

The same conductive material is preferably used for the conductive layer 341 and the conductive layer 342. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 341 and the conductive layer 342. Accordingly, it is possible to employ a Cu-to-Cu (copper-to-copper) direct bonding technique (a technique for achieving electrical continuity by connecting Cu (copper) pads to each other).

### [Display Panel 200C]

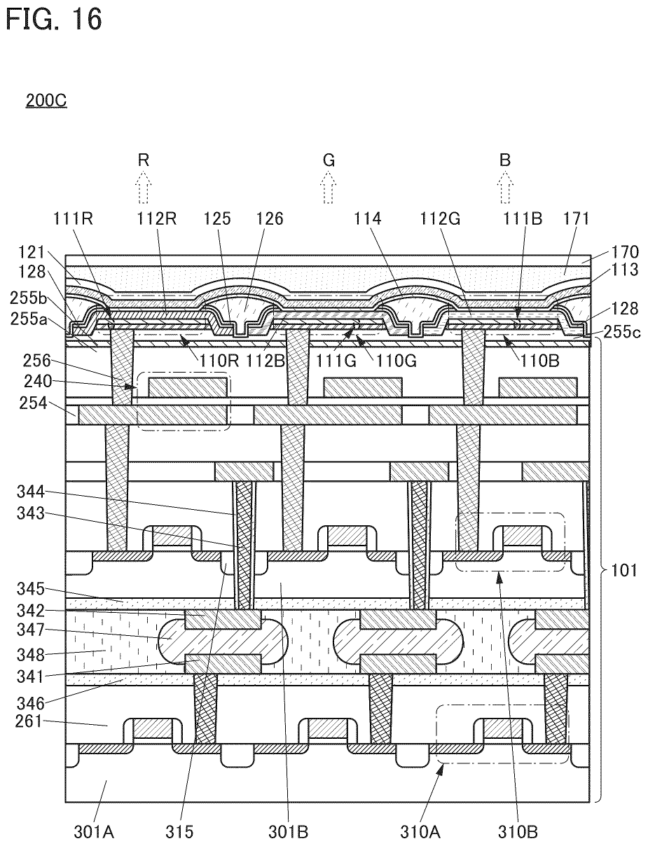

The display panel 200C illustrated in FIG. 16 has a structure where the conductive layer 341 and the conductive layer 342 are bonded to each other through a bump 347.

As illustrated in FIG. 16, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder is used for the bump 347 in some cases. In addition, an adhesive layer 348 may be provided between the insulating layer 345 and the insulating layer 346. Furthermore, in the case where the bump 347 is provided, a structure without the insulating layer 335 and the insulating layer 336 may be employed.

### [Display Panel 200D]

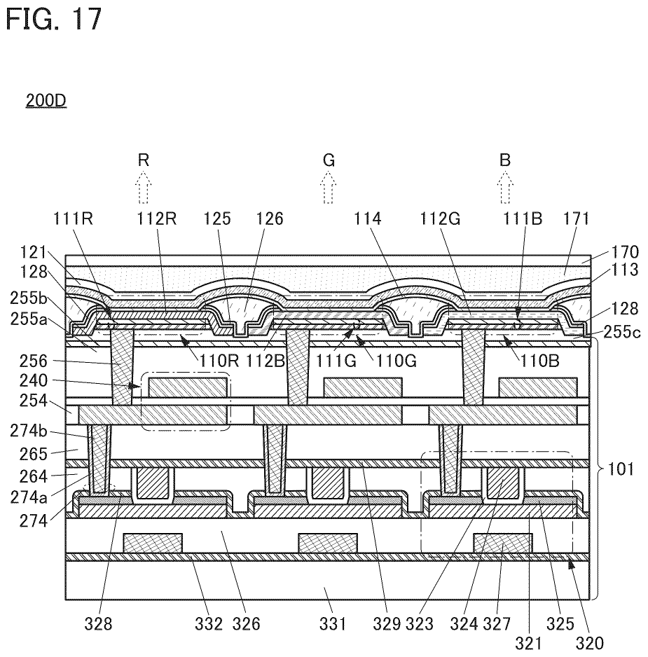

The display panel 200D illustrated in FIG. 17 differs from the display panel 200A mainly in a transistor structure.

A transistor 320 is a transistor (an OS transistor) in which a metal oxide (also referred to as an oxide semiconductor) is employed in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 13A and FIG. 13B.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided on and in contact with the semiconductor layer 321, and functions as a source electrode and a drain electrode.

An insulating layer 328 is provided to cover top surfaces and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with a top surface of the semiconductor layer 321 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like to the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers side surfaces of openings in the insulating layer 265, the insulating layer 329, the insulating layer 264, and the insulating layer 328 and part of a top surface of the conductive layer 325, and a conductive layer 274b that is in contact with atop surface of the conductive layer 274a. In that case, a conductive material in which hydrogen and oxygen are less likely to diffuse is preferably used for the conductive layer 274a.

Note that there is no particular limitation on the structures of the transistors included in the display panel of this embodiment. For example, a planar transistor, a staggered transistor, an inverted staggered transistor, or the like can be used. In addition, the transistor structure may be either atop-gate structure or a bottom-gate structure. Alternatively, gates may be provided above and below a semiconductor layer where a channel is formed.

A structure in which the semiconductor layer where a channel is formed is sandwiched between two gates is employed for the transistor 320. The two gates may be connected to each other and supplied with the same signal to drive the transistor. Alternatively, a potential for controlling the threshold voltage may be applied to one of the two gates and a potential for driving may be applied to the other of the two gates to control the threshold voltage of the transistor.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The bandgap of a metal oxide used for the semiconductor layer of the transistor is preferably greater than or equal to 2 eV, further preferably greater than or equal to 2.5 eV. The use of a metal oxide having a wide bandgap can reduce the off-state current of the OS transistor.

A metal oxide preferably contains at least indium or zinc, and further preferably contains indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

Examples of the metal oxide that can be used for the semiconductor layer include indium oxide, gallium oxide, and zinc oxide. In addition, the metal oxide preferably contains two or three kinds selected from indium, the element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

Note that in the case where a metal oxide is used for the semiconductor layer, it is suitable to form the metal oxide by a sputtering method or an ALD method. In the case where the metal oxide is formed by a sputtering method, productivity can be increased and film density can be increased. In the case where the metal oxide is formed by an ALD method, coverage with a film can be increased.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

When the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of a desired atomic ratio.

Gallium or tin is preferably used as the element M. Note that two or more of the above elements may be used in combination as the element M. A metal oxide with In:M:Zn of 40:1:10 or the neighborhood thereof is preferably used for the semiconductor layer. Specifically, a metal oxide with In:Sn:Zn of 40:1:10 or the neighborhood thereof can be suitably used.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

Alternatively, the semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M.

Alternatively, a stacked structure or the like of one selected from indium oxide, indium gallium oxide, and IGZO, and one selected from IAZO, IAGZO, and ITZO (registered trademark) may be used, for example.

Examples of an oxide semiconductor having crystallinity include a CAAC (c-axis aligned crystalline)-OS and an nc (nanocrystalline)-OS.

An OS transistor has extremely higher field-effect mobility than a transistor using amorphous silicon. In addition, the OS transistor has extremely low leakage current between a source and a drain in an off state (also referred to as off-state current), and charge accumulated in a capacitor that is connected in series with the transistor can be retained for a long period. Furthermore, the power consumption of the display panel can be reduced with the use of the OS transistor.

In addition, to increase the emission luminance of the light-emitting device included in the pixel circuit, the amount of current flowing through the light-emitting device needs to be increased. To increase the current amount, the source-drain voltage of a drive transistor included in the pixel circuit needs to be increased. Since the OS transistor has higher breakdown voltage between the source and the drain than a Si transistor, high voltage can be applied between the source and the drain of the OS transistor. Accordingly, when an OS transistor is used as the drive transistor included in the pixel circuit, the amount of current flowing through the light-emitting device can be increased, so that the emission luminance of the light-emitting device can be increased.

In addition, when transistors operate in a saturation region, a change in source-drain current relative to a change in gate-source voltage is smaller in an OS transistor than in a Si transistor. Accordingly, when an OS transistor is employed as the drive transistor included in the pixel circuit, the amount of current flowing between the source and the drain can be finely set by a change in gate-source voltage; thus, the amount of current flowing through the light-emitting device can be controlled. Therefore, the number of gray levels in the pixel circuit can be increased.

In addition, regarding saturation characteristics of current flowing when transistors operate in a saturation region, even in the case where the source-drain voltage of an OS transistor gradually increases, more stable current (saturation current) can be fed through the OS transistor than through a Si transistor. Thus, by using an OS transistor as the drive transistor, stable current can be fed through the light-emitting device even when the current-voltage characteristics of EL devices vary, for example. In other words, when the OS transistor operates in the saturation region, the source-drain current hardly changes even with an increase in the source-drain voltage; thus, the emission luminance of the light-emitting device can be stable.

As described above, with the use of an OS transistor as the drive transistor included in the pixel circuit, it is possible to achieve “reduction in power consumption,” “increase in emission luminance,” “increase in the number of gray levels,” “inhibition of variation in light-emitting devices,” and the like.

### [Display Panel 200F]

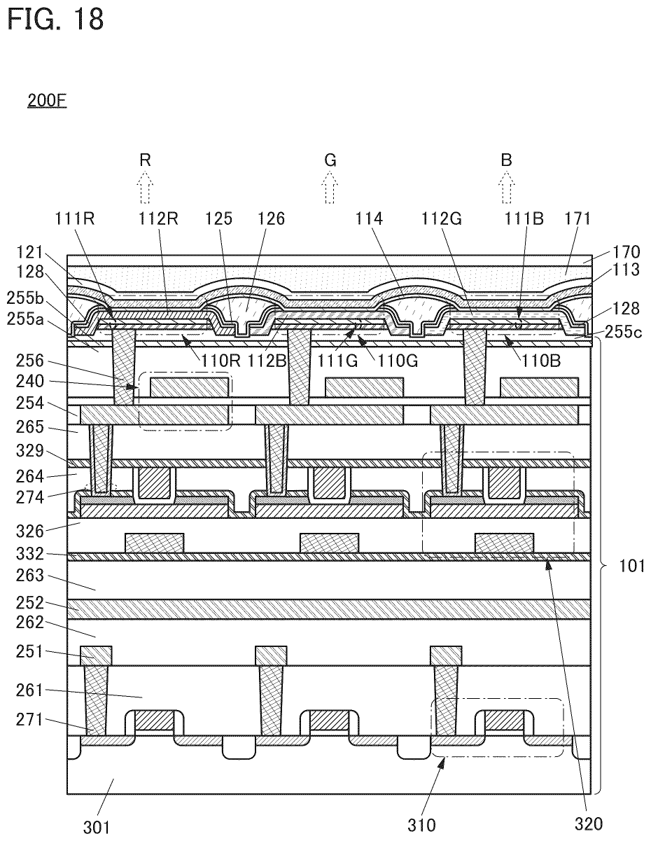

The display panel 200F illustrated in FIG. 18 has a structure where the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. In addition, the transistor 310 can be used as a transistor included in the pixel circuit or a transistor included in a driver circuit (a gate line driver circuit or a source line driver circuit) for driving the pixel circuit. Furthermore, the transistor 310 and the transistor 320 can be used as transistors included in a variety of circuits such as an arithmetic circuit or a memory circuit.

With such a structure, not only the pixel circuit but also the driver circuit and the like can be formed directly under the light-emitting devices; thus, the display panel can be downsized as compared with the case where the driver circuit is provided around a display region.

### [Display Panel 200G]

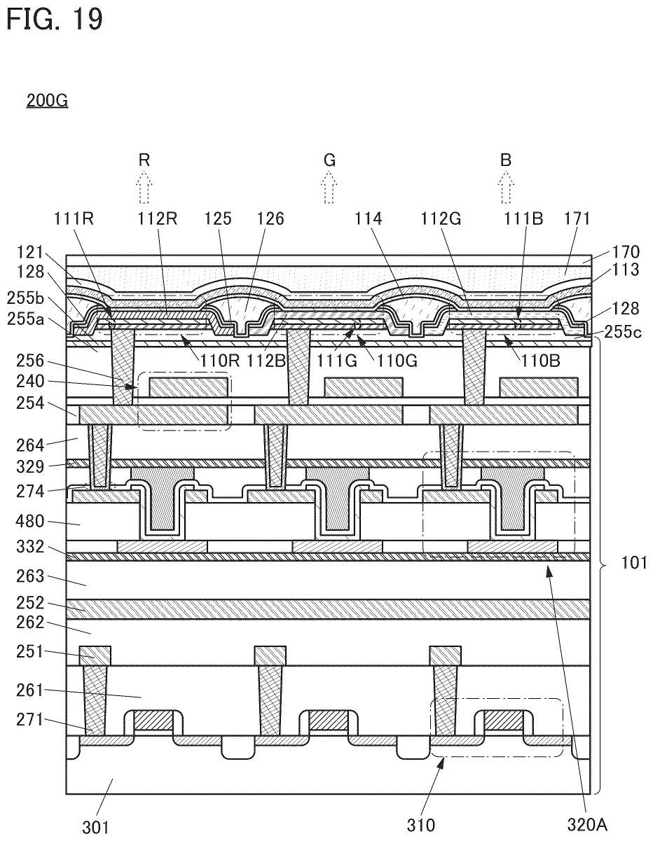

A display panel 200G illustrated in FIG. 19 has a structure where the transistor 320 in the display panel 200F illustrated in FIG. 18 is replaced with a transistor 320A (a vertical transistor). Note that the structure where the transistor 320 is replaced with the transistor 320A can also be applied to the display panel 200D illustrated in FIG. 17.

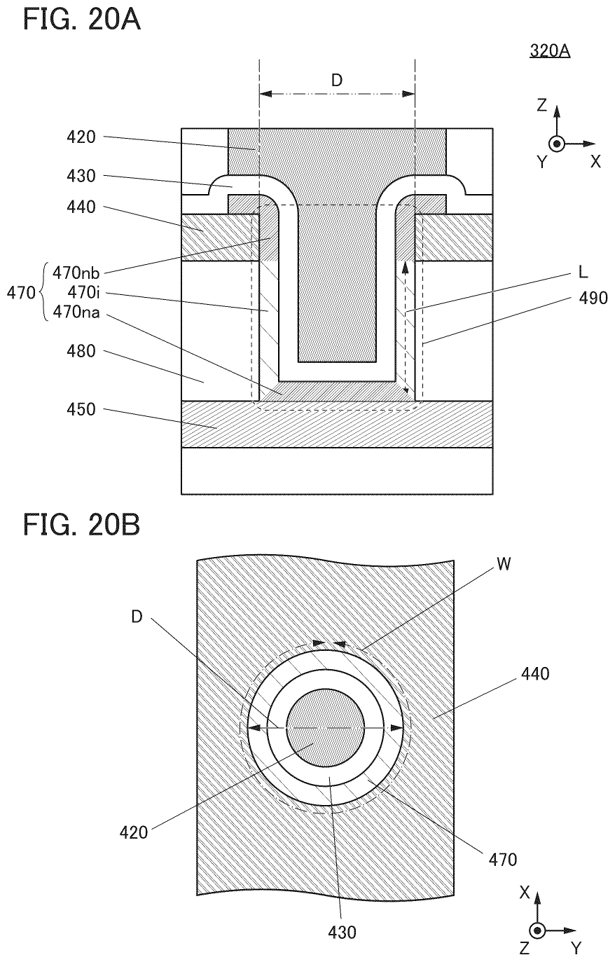

FIG. 20A illustrates a cross-sectional view of the transistor 320A along an X-Z plane. In addition, FIG. 20B illustrates a cross-sectional view along an X-Y plane including a wiring 440.

The transistor 320A includes an oxide semiconductor 470, an insulator 430, and a conductor 420. The oxide semiconductor 470 functions as a semiconductor layer, the insulator 430 functions as agate insulator, and the conductor 420 functions as agate electrode. In addition, a wiring 450 includes a region that functions as one of a source electrode and a drain electrode of the transistor 320A. Furthermore, the wiring 440 includes a region that functions as the other of the source electrode and the drain electrode of the transistor 320A.

An opening portion 490 that penetrates the wiring 440 and the insulator 480 and reaches the wiring 450 is provided. The opening portion 490 has a columnar shape with a substantially circular top surface. With such a structure, memory cells can be miniaturized or highly integrated. Note that a side surface of the opening portion 490 is preferably perpendicular to a top surface of the wiring 450.

At least part of the oxide semiconductor 470 is placed in the opening portion 490. Note that the oxide semiconductor 470 includes, in the opening portion 490, a region that is in contact with a top surface of the wiring 450, regions that are in contact with side surfaces of the wiring 440, and regions that are in contact with side surfaces of the insulator 480.

At least part of the insulator 430 is placed to cover the opening portion 490. At least part of the conductor 420 is placed to be positioned in the opening portion 490. Note that the conductor 420 is preferably provided to be embedded in the opening portion 490, and the conductor 420 preferably has a substantially circular top surface shape in order to increase an integration degree.

As illustrated in FIG. 20A, the oxide semiconductor 470 includes a region 470i, and a region 470na and a region 470nb provided such that the region 470i is sandwiched therebetween.

The region 470na is a region that is in contact with the wiring 450 in the oxide semiconductor 470. At least part of the region 470na functions as one of a source region and a drain region of the transistor 320A. The region 470nb is a region that is in contact with the wiring 440 in the oxide semiconductor 470. At least part of the region 470nb functions as the other of the source region and the drain region of the transistor 320A. As illustrated in FIG. 20B, the wiring 440 is in contact with the entire outer periphery of the oxide semiconductor 470. Thus, the other of the source region and the drain region of the transistor 320A can be formed on the entire outer periphery of a portion formed in the same layer as the wiring 440 in the oxide semiconductor 470.

The region 470i is a region sandwiched between the region 470na and the region 470nb in the oxide semiconductor 470. At least part of the region 470i functions as a channel formation region of the transistor 320A. That is, the channel formation region of the transistor 320A is formed in a portion of the oxide semiconductor 470 that is positioned in a region between the wiring 450 and the wiring 440. It can also be said that the channel formation region of the transistor 320A is positioned in a region that is in contact with the insulator 480 or a region in the vicinity thereof in the oxide semiconductor 470.

The channel length of the transistor 320A is the distance between the source region and the drain region. That is, it can be said that the channel length of the transistor 320A is determined by the thickness of the insulator 480 over the wiring 450. In FIG. 20A, the channel length L of the transistor 320A is indicated by a dashed double-headed arrow. The channel length L is the distance between an end portion of a region where the oxide semiconductor 470 and the wiring 450 are in contact with each other and an end portion of a region where the oxide semiconductor 470 and the wiring 440 are in contact with each other in the cross-sectional view. In other words, the channel length L corresponds to the length of the side surface of the insulator 480 on the opening portion 490 side in the cross-sectional view.

The channel length of a conventional transistor is set by the light exposure limit of photolithography; however, in one embodiment of the present invention, the channel length can be set by the film thickness of the insulator 480. Thus, the transistor 320A can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm). Accordingly, the transistor 320A can have high on-state current.

In addition, the channel formation region, the source region, and the drain region can be formed in the opening portion 490, as described above. Thus, an area occupied by the transistor 320A can be reduced compared to the conventional transistor where a channel formation region, a source region, and a drain region are separately provided on the X-Y plane. Accordingly, pixel density can be increased.

Such a transistor including a channel formation region along the side surface of the insulator 480 in the opening portion 490 is also referred to as a vertical transistor.

In addition, also in the X-Y plane including the channel formation region of the oxide semiconductor 470, the oxide semiconductor 470, the insulator 430, and the conductor 420 are concentrically provided. Thus, a side surface of the conductor 420 that is provided in the center faces a side surface of the oxide semiconductor 470 with the insulator 430 therebetween. That is, in a top view, the entire outer periphery of the oxide semiconductor 470 serves as the channel formation region. In that case, the channel width of the transistor 320A is determined by the length of the outer periphery of the oxide semiconductor 470, for example. In other words, it can be said that the channel width of the transistor 320A is determined by the measurement of the maximum width of the opening portion 490 (the maximum diameter when the opening portion 490 is circular in the top view). In FIG. 20A and FIG. 20B, the maximum width D of the opening portion 490 is indicated by a dashed double-dotted double-headed arrow. In FIG. 20B, the channel width W of the transistor 320A is indicated by a dashed-dotted double-headed arrow. When the measurement of the maximum width D of the opening portion 490 is increased, channel width per unit area can be increased, so that the on-state current can be increased.

In the case where the opening portion 490 is formed by a photolithography method, the maximum width D of the opening portion 490 is set by the light exposure limit of photolithography. In addition, the maximum width D of the opening portion 490 is set by the film thicknesses of the oxide semiconductor 470, the insulator 430, and the conductor 420 that are provided in the opening portion 490. The maximum width D of the opening portion 490 is preferably greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm, for example. Note that in the case where the opening portion 490 is circular in the top view, the maximum width D of the opening portion 490 corresponds to the diameter of the opening portion 490, and the channel width W can be calculated to be “D×π.”

Furthermore, in a memory device according to one embodiment of the present invention, the channel length L of the transistor 320A is preferably smaller than at least the channel width W of the transistor 320A. The channel length L of the transistor 320A according to one embodiment of the present invention is greater than or equal to 0.1 times and less than or equal to 0.99 times as large as the channel width W of the transistor 320A, preferably greater than or equal to 0.5 times and less than or equal to 0.8 times as large as the channel width W of the transistor 320A. With such a structure, a transistor with favorable electrical characteristics and high reliability can be achieved.

When the opening portion 490 is formed to be substantially circular in the top view, the oxide semiconductor 470, the insulator 430, and the conductor 420 are concentrically formed. This makes the distance between the conductor 420 and the oxide semiconductor 470 substantially uniform, so that a gate electric field can be substantially uniformly applied to the oxide semiconductor 470.

It is preferable that a channel formation region of a transistor using an oxide semiconductor in a semiconductor layer contain less oxygen vacancies or have a lower concentration of impurities such as hydrogen, nitrogen, or a metal element than a source region and a drain region. For example, the concentration of aluminum in the channel formation region of the oxide semiconductor is preferably lower than or equal to 1×10²² atoms/cm³, further preferably lower than or equal to 1×10²¹ atoms/cm³, still further preferably lower than or equal to 1×10²⁰ atoms/cm³, yet further preferably lower than or equal to 5×10¹⁹ atoms/cm³, yet still further preferably lower than or equal to 1×10¹⁹ atoms/cm³, yet still further preferably lower than or equal to 5×10¹⁸ atoms/cm³, yet still further preferably lower than or equal to 1×10¹⁸ atoms/cm³.

In some cases, hydrogen in the vicinity of an oxygen vacancy forms a defect that is an oxygen vacancy into which hydrogen enters (hereinafter sometimes referred to as VoH), which generates an electron serving as a carrier. Thus, it is preferable that VoH be also reduced in the channel formation region. Hence, the channel formation region of the transistor is a high-resistance region having a low carrier concentration. Accordingly, the channel formation region of the transistor can be regarded as an i-type (intrinsic) or substantially i-type region.

The source region and the drain region of the transistor using an oxide semiconductor in the semiconductor layer are regions that have lower resistance than the channel formation region by having increased carrier concentrations because of containing more oxygen vacancies or more VoH or having higher concentrations of impurities such as hydrogen, nitrogen, or a metal element. In other words, the source region and the drain region of the transistor are n-type regions having higher carrier concentrations and lower resistance than the channel formation region.

Note that although the opening portion 490 is provided such that the side surfaces of the opening portion 490 are perpendicular to the top surface of the wiring 450 in FIG. 20A and the like, the present invention is not limited thereto. For example, the side surfaces of the opening portion 490 may each have a tapered shape.

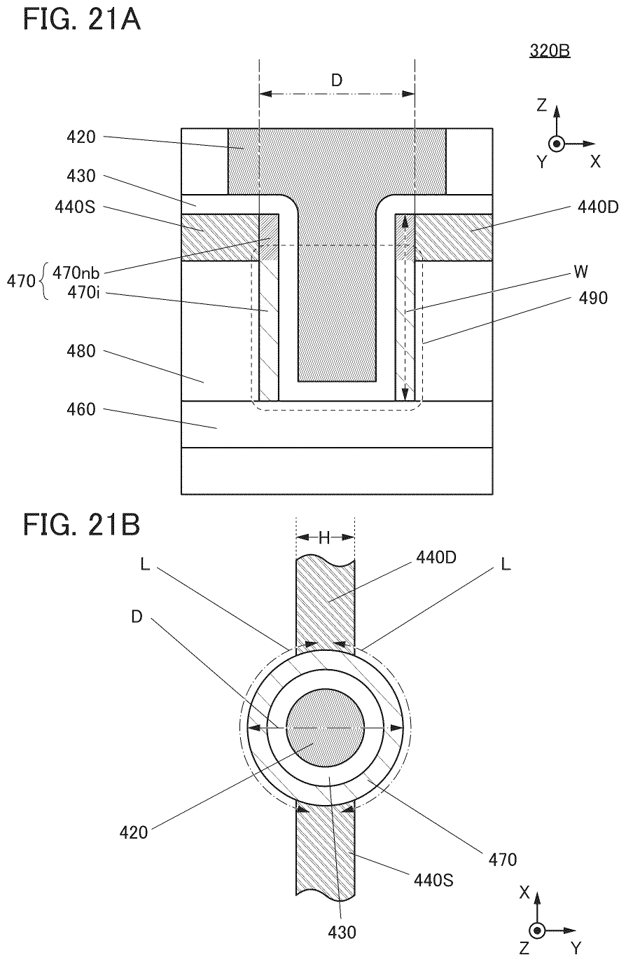

FIG. 21A illustrates a cross-sectional view of a transistor 320B in an X-Z plane that is a vertical transistor having a structure different from that in FIG. 20. In addition, FIG. 21B illustrates a cross-sectional view of the transistor 320B in an X-Y plane.

The transistor 320B differs from the transistor 320A mainly in not including the wiring 450, being provided over an insulator 460, including a wiring 440S and a wiring 440D instead of the wiring 440, and the shape of the oxide semiconductor 470. The wiring 440S has a function of a source electrode, and the wiring 440D has a function of a drain electrode.

The oxide semiconductor 470 has a ring-like shape. Specifically, the oxide semiconductor 470 includes, in the opening portion 490, a region that is in contact with a side surface of the wiring 440S, a region that is in contact with a side surface of the wiring 440D, and regions that are in contact with side surfaces of the insulator 480. Here, a structure is employed in which the oxide semiconductor 470 is not contact with top surfaces of the wiring 440S and the wiring 440D. The oxide semiconductor 470 having such a shape can be formed by processing with anisotropic etching, for example.

As illustrated in FIG. 21B, the width H of each of the wiring 440S and the wiring 440D is smaller than the maximum width D of the opening portion 490. In that case, the circumference direction of the opening portion 490 corresponds to the channel length direction of the transistor 320B. Here, since the oxide semiconductor 470 has the ring-like shape, two current paths (i.e., channels) from the wiring 440S to the wiring 440D exist. Note that the oxide semiconductor 470 does not necessarily have the ring-like shape.

The channel length can be controlled by the shape and size of the opening portion 490. For example, in the case where the channel length is to be increased, the perimeter of the opening portion 490 is made long. In addition, although an example where the opening portion 490 is circular in a plan view is illustrated, the present invention is not limited thereto. For example, in the plan view, the opening portion 490 can have an elliptical shape, a quadrilateral shape with rounded corners, or the like other than a circular shape. Alternatively, the opening portion 490 may have a regular polygonal shape such as an equilateral triangle shape, a square shape, or an equilateral pentagon shape, or a polygonal shape other than the regular polygonal shape. Alternatively, when the opening portion 490 has a concave polygonal shape, which is a polygonal shape with at least one interior angle greater than 180°, such as a star polygonal shape, the channel width can be increased. Alternatively, the opening portion 490 may have a closed curve or the like where an elliptical shape, a polygonal shape with rounded corners, a straight line, and a curve are combined. In that case, it is preferable to calculate the maximum width of the opening portion 490 as appropriate depending on the shape of the uppermost part of the opening portion 490. For example, in the plan view, in the case where the opening portion has a square shape or a rectangular shape, the maximum width of the opening portion 490 is preferably the length of a diagonal line of the uppermost part of the opening portion 490.

In addition, as illustrated in FIG. 21A, the height of the oxide semiconductor 470 corresponds to the channel width W of the transistor 320B. Therefore, the channel width W of the transistor 320B can be controlled by the thickness of the insulator 480. Thus, the transistor 320B can have an extremely small channel width W less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm).

The transistor 320A is a transistor that can have extremely small channel length and large channel width and can achieve high on-state current. Meanwhile, the transistor 320B is a transistor that can have extremely small channel width and large channel length and can achieve moderate on-state current, which facilitates design. Some of manufacturing steps can be common to the transistor 320A and the transistor 320B, and the transistor 320A and the transistor 320B can be separately fabricated over the same substrate. For example, in a display device, the transistor 320B can be employed as a drive transistor for controlling current flowing through a light-emitting element, and the transistor 320A can be employed as a transistor that functions as a switch.

At least part of this embodiment can be implemented in combination with the other embodiment and an example described in this specification as appropriate.

### REFERENCE NUMERALS

PIC_D: pixel, PIX_A: pixel, PIX_B: pixel, PIX_C: pixel, PIX_D: pixel, PIX: pixel, 10: electronic device, 11: housing, 12: display unit, 13: band, 14a: direction detection sensor, 14b: direction detection sensor, 14: direction detection sensor, 20: display panel, 21: region, 22: region, 23: region, 25: eye, 30: optical device, 31: half mirror, 32: lens, 33: retardation plate, 34: reflective polarizing plate, 35: lens, 62: linear polarizing plate, 63: retardation plate, 70: pixel, 71: subpixel, 74: pixel array, 75: circuit, 76: circuit, 77: layer, 78: layer, 79: layer, 100a: display panel, 100b: display panel, 100: display panel, 101: substrate, 110a: light-emitting element, 110B: light-emitting element, 110b: light-emitting element, 110c: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 116B: coloring layer, 116G: coloring layer, 116R: coloring layer, 121: protective layer, 122: insulating layer, 123: insulating layer, 124a: pixel, 124b: pixel, 125: insulating layer, 126: resin layer, 128: layer, 140: connection portion, 150: pixel, 170: substrate, 171: adhesive layer, 200A: display panel, 200B: display panel, 200C: display panel, 200D: display panel, 200F: display panel, 200G: display panel, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 420: conductor, 430: insulator, 440D: wiring, 440S: wiring, 440: wiring, 450: wiring, 460: insulator, 470i: region, 470na: region, 470nb: region, 470: oxide semiconductor, 480: insulator, and 490: opening portion.

1. A head-mounted type electronic device comprising:
a display panel;
an optical device; and
a first sensor,
wherein the optical device is configured to converge light emitted from a display portion of the display panel to emit the converged light to a user's eye,
wherein the first sensor is configured to support head tracking,
wherein the display portion comprises a first region comprising a pixel array center, a second region adjacent to the first region, and a third region adjacent to the second region,
wherein a definition of the first region is higher than a definition of the second region and the definition of the second region is higher than a definition of the third region, and
wherein a video of the display portion follows a user's head movement so that a user's line of sight is maintained in the first region using the head tracking.

2. The head-mounted type electronic device according to claim 1, further comprising a second sensor,
wherein the second sensor is configured to support eye tracking, and
wherein the video of the display portion is moved in a direction opposite to an inclined direction of the user's line of sight so that the user's line of sight is maintained in the first region using the eye tracking.

3. The head-mounted type electronic device according to claim 1, wherein the first region, the second region, and the third region have the same pixel density.

4. The head-mounted type electronic device according to claim 1, wherein a pixel density of the first region is higher than a pixel density of the second region and the pixel density of the second region is higher than a pixel density of the third region.

5. The head-mounted type electronic device according to claim 1, wherein, when the display portion is visually recognized through the optical device, display of the first region is visually recognized in a region where a viewing angle ranges from 0° to 50° and display of the third region is visually recognized in a region where the viewing angle is higher than or equal to 70°.

6. The head-mounted type electronic device according to claim 1, wherein a pixel included in the third region does not comprise a subpixel.

7. The head-mounted type electronic device according to claim 1, wherein a pixel included in the third region emits green light or white light.

8. The head-mounted type electronic device according to claim 1,
wherein the display portion is divided into a plurality of regions,
wherein each of the plurality of regions comprises a pixel and a driver circuit for driving the pixel, and
wherein the pixel overlaps with the driver circuit.

9. The head-mounted type electronic device according to claim 8,
wherein the pixel comprises a transistor comprising a metal oxide in a channel formation region, and
wherein the driver circuit comprises a transistor comprising silicon in a channel formation region.

10. The head-mounted type electronic device according to claim 1, wherein the display panel comprises an organic EL element.

11. A method for operating an electronic device comprising a display panel, an optical device, and a first sensor, the method comprising the steps of:
performing head tracking using the first sensor; and
adjusting a video of the display panel so that it follows a user's head movement using the head tracking so that a user's line of sight through the optical device enters a first region where a viewing angle ranges from 0° to 50°.

12. A method for operating an electronic device comprising a display panel, an optical device, a first sensor, and a second sensor, the method comprising the steps of:
performing head tracking using the first sensor;
adjusting a video of the display panel so that it follows a user's head movement using the head tracking so that a user's line of sight through the optical device enters a first region where a viewing angle ranges from 0° to 50°;
performing eye tracking using the second sensor; and
moving the video of the display panel in a direction opposite to an inclined direction of the user's line of sight by the eye tracking so that the user's line of sight is maintained in the first region.

13. The method for operating an electronic device according to claim 11, further comprising the steps of:
displaying the video in the first region with a first definition; and
displaying the video in a second region provided outside the first region with a second definition,
wherein the first definition is higher than the second definition, and
wherein the definition in the second region is lower than the definition in the first region by inputting the same image data into a plurality of pixels.

14. The method for operating an electronic device according to claim 11,
wherein the video is displayed at a first frame rate in the first region,
wherein the video is displayed at a second frame rate in a second region provided outside the first region, and
wherein the first frame rate is higher than the second frame rate.
